(19) United States
(12) Patent Application Publication
(10) Pub. No.: US 2007/0170588 A1
(43) Pub. Date: Jul. 26, 2007

(54) Connection structure and fabrication method for the same

(76) Inventor: Satoru Goto, Kyoto (JP)

Correspondence Address: MCDERMOTT WILL & EMERY LLP, 600 13TH STREET, N.W., WASHINGTON, DC, 20005-3096, US

(21) Appl. No.: 11/544,646

(22) Filed: Oct. 10, 2006

(30) Foreign Application Priority Data
Jan. 25, 2006 (JP) JP 2006-016073

(51) Int. Cl. H01L 29/40; H01L 21/44

(52) U.S. Cl. 257/754; 438/660; 438/664; 438/637; 257/758

(57) ABSTRACT

A conductive layer is formed in or on a substrate. A first metal film is then formed on the substrate including the conductive layer. The substrate is then subjected to heat treatment to allow the first metal film to react with the conductive layer to thereby form a silicide film selectively on the conductive layer. A second metal film is then formed only on the silicide film by selective CVD. An insulating film is then formed over the substrate including the second metal film. A predetermined region of the insulating film is removed to form a contact hole reaching the second metal film. The inside of the contact hole is cleaned to remove a degenerated layer formed on the surface of the second metal film existing on the bottom of the contact hole.

### CROSS-REFERENCE TO RELATED APPLICATIONS

The disclosure of Japanese Patent Application No. 2006-016073 filed Jan. 25, 2006 including specification, drawing and claims is incorporated herein by reference in its entirely.

### BACKGROUND OF THE INVENTION

The present invention relates to a connection structure and a fabrication method for the same, and more particularly, to a structure of a connection portion in a semiconductor device and a fabrication method for the same.

In semiconductor integrated circuit devices, as semiconductor elements have been made finer with the trend of higher speed and higher integration, it has become essential to form shallow diffusion layers as source/drain regions. By making diffusion layers shallow, however, the resistance of the diffusion layers becomes high, and a problem arises that the contact resistance between the diffusion layers and plugs forming connections with the diffusion layers becomes extremely high.

Conventionally, as a general solution for the problem of high contact resistance, a salicide technology has been adopted. This technology includes depositing a metal film on each of diffusion layers as source/drain regions and heat-treating the resultant layer to form a low-resistance layer of an alloy of the metal and Si called silicide in a self-aligned manner.

A conventional fabrication method for a connection structure using Co silicide will be described with reference to FIGS. 9A through 9G (see Japanese Laid-Open Patent Publication No. 10-055982, for example). FIGS. 9A through 9G are cross-sectional views showing conventional fabrication process steps for a NMIS transistor and its surroundings of a semiconductor integrated circuit device.

In the conventional fabrication method for a semiconductor integrated circuit device, first, as shown in FIG. 9A, a p-type impurity such as boron is ion-implanted in a predetermined region of a silicon substrate 100 doped with an n-type impurity, to form a p-well 105. A silicon oxide film 101 and a silicon nitride film 102 are sequentially deposited on the silicon substrate 100, and the silicon nitride film 102 is patterned by reactive ion etching using a resist pattern (not shown) formed by lithography as a mask. The patterning of the silicon nitride film 102 is made so as to remove portions of the silicon nitride film 102 corresponding to regions in which element isolation oxide films are to be formed. Using the resultant silicon nitride film 102 as a mask, a p-type impurity such as boron, for example, is ion-implanted to form channel stoppers 104.

As shown in FIG. 9B, the resultant silicon substrate 100 is heat-treated by thermal oxidation to oxidize regions uncovered with the silicon nitride film 102 to form element isolation oxide films 103. The silicon nitride film 102 and the silicon oxide film 101 are then removed, and an insulating film to serve as a gate insulating film is formed on the silicon substrate 100 by thermal oxidation. A polycrystal silicon film is deposited on the insulating film for serving as a gate insulating film to a thickness of 200 nm by CVD, and then patterned together with the insulating film by reactive ion etching using a resist pattern (not shown) formed by lithography as a mask, to form a gate electrode 107 made of polycrystal silicon and a gate insulating film 106.

As shown in FIG. 9C, an n-type impurity such as arsenic or phosphorus is ion-implanted in the silicon substrate 100, to form LDD layers 108. A silicon oxide film is then deposited over the entire surface of the silicon substrate 100 and subjected to anisotropic overall etching to form sidewalls 109 made of the insulating film on the sidewalls of the gate electrode 107. In this state, silicon is exposed on the portions of the silicon substrate 100 located outside with respect to the sidewalls 109 and polycrystal silicon is exposed on the top of the gate electrode 107.

As shown in FIG. 9D, an n-type impurity such as arsenic or phosphorus is ion-implanted in the silicon substrate 100 to form source/drain regions 110 as high-density diffusion layers. The source/drain regions 110 are then activated by being subjected to heat treatment for activation in a nitrogen atmosphere.

As shown in FIG. 9E, Co is deposited to a thickness of 15 nm by sputtering and then subjected to first heat treatment in a nitrogen atmosphere to form silicide films 111 on the Si-exposed source/drain regions 110 and gate electrode 107. Selective etching is then performed by wet etching to remove unreacted Co. As an example of the wet etching, a liquid mixture of sulfuric acid and hydrogen peroxide, for example, may be used. Thereafter, the silicide films 111 are subjected to second heat treatment to reduce the resistance of the silicide films 111.

As shown in FIG. 9F, a liner insulating film 118 made of SiN and an interlayer insulating film 112 made of SiO₂ are deposited by CVD and flattened by CMP. A resist pattern (not shown) is formed by lithography, and the interlayer insulating film 112 is dry-etched using the resist pattern as a mask to expose the top surfaces of the underlying source/drain regions 110. This process is herein called contact etching. After subsequent known ashing and cleaning, the portions of the liner insulating film 118 lying under the bottoms of the contacts are dry-etched away. This process is herein called liner etching. The known ashing and cleaning are then performed again.

As shown in FIG. 9G, Ti and TiN are deposited by sputtering on the inner surfaces of the contact holes opened to reach the top surfaces of the underlying source/drain regions 110 and the gate electrode 107, W was then deposited by MOCVD, and W existing outside the contact holes is removed by CMP. Contact plugs 114 are thus formed.

### SUMMARY OF THE INVENTION

In the conventional fabrication method described above, it has become evident from experiments carried out by the inventors of the present invention that in the contact plug formation process, a high-resistance degenerated layer made of an oxide is formed on the bottom of each contact plug, causing contact failure.

The reason why such a degenerated layer is formed on the bottom of each contact hole will be described with reference to FIG. 10. As shown in FIG. 10, with the execution of the contact etching and the liner etching, the silicide film 111 exposed on the bottom of the contact hole is oxidized with oxygen contained in an etching gas and with the ashing after the etching, forming a degenerated layer 121 made of an oxide film. The degenerated layer 121 further grows with heat treatment and the like performed after formation of the contact plug.

Co was described as an example of metal constituting the silicide in the above prior art description. However, in the case of Ni to be used in the next generation, formation of a degenerated layer will occur more significantly.

The material TiN in the contact plug in the conventional technology serves as a reaction prevention layer for preventing solid phase reaction between the silicide film and metal during heat treatment. However, the contact plug is unable to suppress growth of a degenerated layer in a process preceding the formation of the contact plug.

An object of the present invention is providing a connection structure capable of preventing formation of a high-resistance degenerated layer during contact etching and liner etching in a connection portion formation process, and a fabrication method for such a connection structure.

The connection structure of the first embodiment of the present invention includes: a conductive layer formed in or on a substrate; a silicide film formed in a predetermined region on the conductive layer; a metal film formed on the silicide film; an insulating film formed over the substrate including the metal film; and a contact plug formed in the insulating film, the bottom of the contact plug being in contact with the metal film.

In the connection structure of the first embodiment of the present invention, a metal film is formed on the silicide film. During contact etching and subsequent ashing, therefore, the metal film is oxidized, preventing oxidation of the silicide film underlying the metal film. The oxidized metal film (degenerated layer) can be selectively removed in a subsequent cleaning process. Hence, the reliability of the contact plug can be enhanced.

The connection structure of the second embodiment of the present invention includes: a conductive layer formed in or on a substrate; a first silicide film formed in a predetermined region on the conductive layer; a second silicide film formed on the first silicide film; an insulating film formed over the substrate including the second silicide film; and a contact plug formed in the insulating film, the bottom of the contact plug being in contact with the second silicide film.

In the connection structure of the second embodiment of the present invention, during contact etching and subsequent ashing, the second silicide film is oxidized, preventing oxidation of the first silicide film. The oxidized silicide film can be easily removed in a subsequent etching process. Hence, the reliability of the contact plug can be enhanced.

In the connection structure of the second embodiment of the present invention, the first silicide film and the second silicide film may be silicide films including a same element.

In the connection structure of the second embodiment of the present invention, the first silicide film and the second silicide film may be silicide films including different elements from each other.

The fabrication method for a connection structure of the first embodiment of the present invention includes the steps of: (a) forming a conductive layer in or on a substrate; (b) forming a first metal film on the conductive layer; (c) forming a silicide film selectively on the conductive layer by performing heat treatment to allow the first metal film to react with the conductive layer; (d) forming a second metal film only on the silicide film; (e) forming an insulating film over the substrate including the second metal film; (f) forming a contact hole reaching the second metal film by removing a predetermined region of the insulating film; and (g) removing a degenerated layer formed on the surface of the second metal film existing on the bottom of the contact hole by cleaning the inside of the contact hole.

In the fabrication method of the first embodiment of the present invention, the second metal film is oxidized in the step (f) of forming a contact hole, and thus the silicide film can be prevented from being oxidized. The oxidized second metal film can be easily removed in the step (g). Hence, a highly-reliable connection structure can be formed.

In the fabrication method of the first embodiment of the present invention, in the step (d), the second metal film may be formed only on the silicide film by selective CVD.

In the fabrication method of the first embodiment of the present invention, in the step (d), the second metal film may be formed over the substrate including the silicide film, and then the second metal film may be selectively removed using a mask to be left behind only on the silicide film.

The fabrication method for a connection structure of the second embodiment of the present invention includes the steps of: (a) forming a conductive layer in or on a substrate; (b) forming a first metal film on the conductive layer; (c) forming a silicide film selectively on the conductive layer by performing heat treatment to allow the first metal film to react with the conductive layer; (d) forming a first insulating film over the substrate including the silicide film; (e) forming a second insulating film on the first insulating film; (f) forming a contact hole reaching the first insulating film by removing a predetermined region of the second insulating film; and (g) removing the first insulating film exposed in the contact hole by sputter etching to allow the silicide film to be exposed in the contact hole.

In the fabrication method of the second embodiment of the present invention, the silicon oxide film remaining on the bottom of the contact hole can be removed in the step (g). Since the sputter etching in this step involves no use of oxygen or fluorocarbon gas, no subsequent ashing is required. Hence, with no formation of a degenerated layer due to ashing, a highly-reliable connection structure can be formed.

In the fabrication method of the second embodiment of the present invention, in the step (f), the etching rate ratio of the second insulating film to the first insulating film may be 3 or more.

The fabrication method for a connection structure of the third embodiment of the present invention includes the steps of: forming a conductive layer in or on a substrate; forming a first metal film on the conductive layer; forming a first silicide film selectively on the conductive layer by performing heat treatment to allow the first metal film to react with the conductive layer; forming a second metal film on the conductive layer; forming a second silicide film selectively on the first silicide film by performing heat treatment to allow the second metal film to react with the first silicide film; forming an insulating film over the substrate including the second silicide film; forming a contact hole reaching the second silicide film by removing a predetermined region of the insulating film; and removing a degenerated layer formed on the surface of the second silicide film existing on the bottom of the contact hole by sputter etching.

In the fabrication method of the third embodiment of the present invention, during contact etching and subsequent ashing, the second silicide film is oxidized, preventing oxidation of the first silicide film. The oxidized silicide film can be easily removed in a subsequent etching process. Hence, a highly-reliable connection structure can be formed.

In the fabrication method of the third embodiment of the present invention, the first silicide film and the second silicide film may be silicide films including a same element.

In the fabrication method of the third embodiment of the present invention, the first silicide film and the second silicide film may be silicide films including different elements from each other.

In the fabrication method of the first to third embodiments of the present invention, the heat treatment may be performed by rapid thermal annealing (RTA).

### BRIEF DESCRIPTION OF THE DRAWINGS

FIGS. 1A through 1G are cross-sectional views showing fabrication process steps for a connection structure in Embodiment 1 of the present invention.

FIG. 2 is a graph showing the relationship between the ashing time and the W surface oxidation amount.

FIGS. 3A through 3E are cross-sectional views showing fabrication process steps for a connection structure in Embodiment 2 of the present invention.

FIGS. 4A through 4E are cross-sectional views showing fabrication process steps for a connection structure in Embodiment 3 of the present invention.

FIGS. 5A through 5E are cross-sectional views showing fabrication process steps for a connection structure in Embodiment 4 of the present invention.

FIG. 6 is a cross-sectional view showing the state observed when a thick silicide film is formed by one-time silicidation.

FIGS. 7A through 7E are cross-sectional views showing fabrication process steps for a connection structure in Embodiment 5 of the present invention.

FIG. 8 is a graph showing the relationship between the Ti oxidation time and the Ti surface oxidation amount.

FIGS. 9A through 9G are cross-sectional views showing conventional fabrication process steps for a NMIS transistor and its surroundings of a semiconductor integrated circuit device.

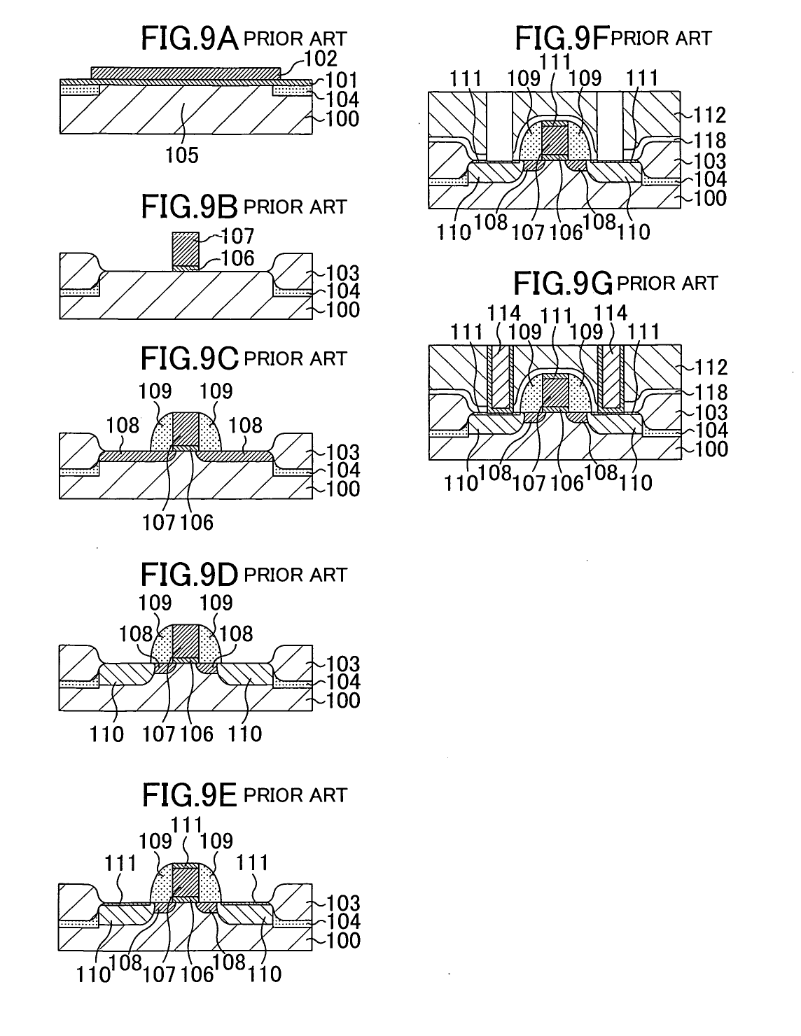

FIG. 10 is a view presented to explain the cause of formation of a degenerated layer on the bottom of a contact hole.

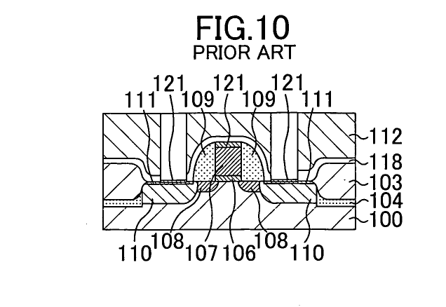

### DESCRIPTION OF THE PREFERRED EMBODIMENTS

Hereinafter, preferred embodiments of the present invention will be described with reference to the accompanying drawings.

### Embodiment 1

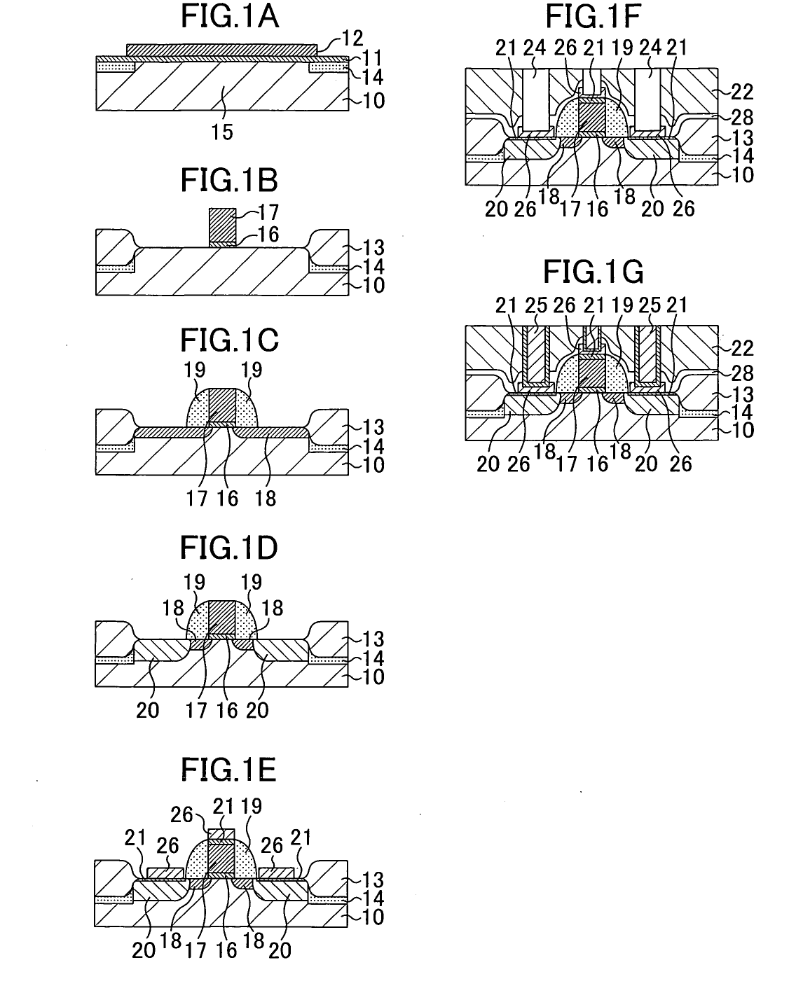

A fabrication method for a connection structure in Embodiment 1 of the present invention will be described with reference to FIGS. 1A through 1G. FIGS. 1A through 1G are cross-sectional views showing process steps of the fabrication method in Embodiment 1.

In this embodiment, description will be made focusing attention on one NMIS transistor and its surroundings constituting a semiconductor integrated circuit device.

In the fabrication method for a connection structure in this embodiment, first, as shown in FIG. 1A, a p-type impurity such as boron is ion-implanted in a predetermined region of a silicon substrate 10 doped with an n-type impurity, to form a p-well 15. A silicon oxide film 11 and a silicon nitride film 12 are then deposited on the n-type impurity-doped silicon substrate 10. A resist pattern (not shown) is formed by lithography, and using the resist pattern as a mask, the silicon nitride film 12 is then patterned by reactive ion etching. The patterning of the silicon nitride film 12 is made so as to remove portions of the silicon nitride film 102 corresponding to regions in which element isolation oxide films 13 are to be formed in a later step. Using the resultant silicon nitride film 12 as a mask, a p-type impurity such as boron, for example, is ion-implanted to form channel stoppers 14.

As shown in FIG. 1B, the resultant silicon substrate 10 is heat-treated by thermal oxidation to oxidize regions uncovered with the silicon nitride film 12 to form the element isolation oxide films 13. The silicon nitride film 12 and the silicon oxide film 11 are then removed, and an insulating film to serve as a gate insulating film is formed on the silicon substrate 10 by thermal oxidation. A polycrystal silicon film is then deposited on the resultant insulating film to a thickness of 200 nm by CVD. A resist pattern (not shown) is formed on the polycrystal silicon film by lithography, and reactive ion etching is performed using the resist pattern as a mask to form a gate electrode 17 made of polycrystal silicon and a gate insulating film 16.

As shown in FIG. 1C, an n-type impurity such as arsenic or phosphorus is ion-implanted in the silicon substrate 10, to form LDD layers 18. A silicon oxide film is then deposited over the entire surface of the silicon substrate 10 and subjected to anisotropic overall etching, to form sidewalls 19 made of an insulating film on the sidewalls of the gate electrode 17. In this state, silicon is exposed on the portions of the silicon substrate 10 located outside with respect to the sidewalls 19, and polycrystal silicon is exposed on the top surface of the gate electrode 17.

As shown in FIG. 1D, an n-type impurity such as arsenic and phosphorus is ion-implanted in the silicon substrate 10 to form source/drain regions 20 made of a high-density diffusion layer. The source/drain regions 20 are then activated by being subjected to heat treatment for activation in a nitrogen atmosphere.

As shown in FIG. 1E, Ni is deposited to a thickness of 15 nm by sputtering and then subjected to first heat treatment in a nitrogen atmosphere, to form silicide films 21 on the Si-exposed source/drain regions 20 and gate electrode 17. Selective etching is then performed using wet etching to remove unreacted Ni. As an example of conditions for the wet etching, a liquid mixture of sulfuric acid and hydrogen peroxide, for example, may be used. Thereafter, the silicide films 21 are subjected to second heat treatment to reduce the resistance of the silicide films 21.

Subsequently, W 26 is grown on only the resultant silicide films 21 to a thickness of 30 nm by known selective CVD. As an example of conditions for the selective CVD, WF₆, SiH₄ and H₂ may be supplied at respective flow rates of 20 ml/min, 10 ml/min and 100 ml/min, the pressure during the film deposition may be set at 6650 Pa, and the substrate temperature may be set at 400° C.

The selective CVD for the W 26 is based on the principle that W grows with reduction of WF₆ as a material gas. WF₆ is reduced with SiH₄ (WF₆+3/2 SiH₄→W+3/2 SiF₄+3H₂) to grow W. In the selective CVD, reduction further occurs with the underlying metal (silicide), and thus W 26 can be grown only on the silicide films 21.

As shown in FIG. 1F, a liner insulating film 28 made of SiN and an interlayer insulating film 22 made of SiO₂ are deposited to respective thicknesses of 40 nm and 900 nm by CVD and flattened by CMP. A resist pattern (not shown) is formed on the interlayer insulating film 22 by lithography, and using the resist pattern as a mask, the interlayer insulating film 22 is subjected to contact etching. During this etching, the liner insulating film 28 serves as an etching stopper. Ashing is then performed, followed by cleaning. The liner insulating film 28 is then subjected to liner etching, to form contact holes 24. Ashing is then performed, followed by cleaning.

As an example of conditions for the above contact etching, a dual-frequency RIE etching apparatus may be used, C₄F₈, Ar and O₂ may be supplied as etching gases at respective flow rates of 30 ml/min, 1500 ml/min and 20 ml/min, the RF power may be set at 1200 W for the upper electrode and 2000 W for the lower electrode, the pressure in the etching atmosphere may be set at 15 Pa, and the substrate temperature may be set at 20° C.

As an example of conditions for the above liner etching, a dual-frequency RIE etching apparatus may be used, CHF₃, Ar and O₂ are supplied as etching gases at respective flow rates of 15 ml/min, 1300 ml/min and 20 ml/min, the RF power may be set at 1800 W for the upper electrode and 100 W for the lower electrode, the pressure in the etching atmosphere may be set at 15 Pa, and the substrate temperature may be set at 20° C.

As an example of the above ashing, O₂ may be supplied as an ashing gas at a flow rate of 100 ml/min, the power may be set at 2000 W for the upper electrode, the pressure in the ashing atmosphere may be set at 50 Pa and the substrate temperature may be set at 20° C. As an example of the above cleaning, an alkali cleaning solution containing NH₃, H₂O₂ and H₂O may be used with a ratio of NH₃:H₂O₂:H₂O of 1:1:10.

As shown in FIG. 1G, Ti and TiN are deposited inside the contact holes 24 by sputtering, and then W is deposited by MOCVD. W existing outside the contact holes is removed by CMP. The contact plugs 25 are thus formed.

In this embodiment, in which W is formed on each silicide film, oxidation of W takes place during the contact etching and the subsequent ashing process, preventing the silicide film underlying the W from being oxidized. The oxidized W (degenerated layer) can be selectively removed in the subsequent cleaning process.

In particular, W can be made to grow only on the silicide films by a known selective CVD technology. Also, the oxidized W (degenerated layer) can be easily removed with an alkali solution of pH 7 or higher containing NH₄OH as a major ingredient, and thus is less likely to damage the underlying silicide film. Moreover, with the formation of W above the silicide film, the degenerated layer will be formed above the shallow junction. Thus, a highly-reliable contact plug can be formed.

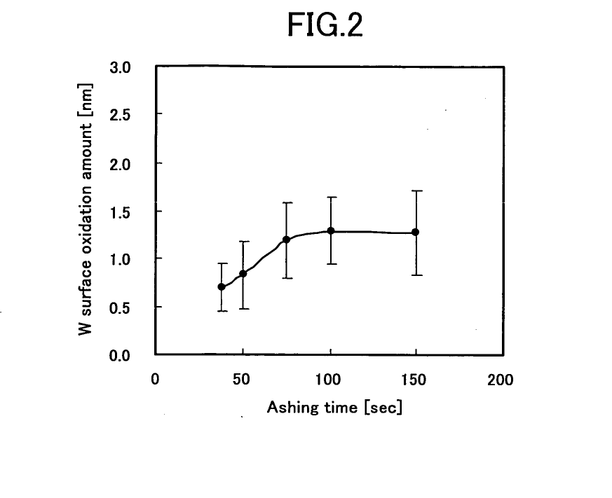

FIG. 2 shows the relationship between the ashing time and the W surface oxidation amount. It is found from FIG. 2 that with increase of the ashing time, the W oxidation amount tends to be saturated and thus the oxidation rate is lowered. In other words, it is considered that with progress of the oxidation of W, the resultant W oxide itself serves as an oxidation prevention layer, preventing the underlying silicide layer from being oxidized even though oxygen is supplied during the contact etching and the ashing.

Although a NMIS transistor was exemplified to describe the present invention in this embodiment, such a connection portion can also be formed for a PMIS transistor by substantially the same technique, and substantially the same effect can be obtained.

### Embodiment 2

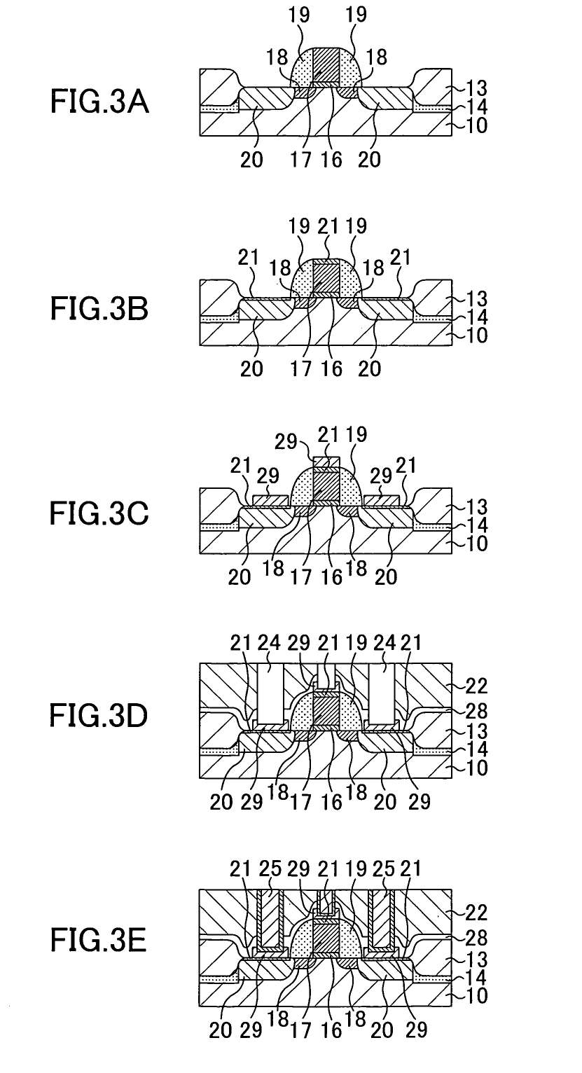

A fabrication method for a connection structure in Embodiment 2 of the present invention will be described with reference to FIGS. 3A through 3E. FIGS. 3A through 3E are cross-sectional views showing process steps of the fabrication method in Embodiment 2.

In the fabrication method in this embodiment, the method in Embodiment 1 is followed until the formation of the source/drain regions 20 as shown in FIG. 3A.

Thereafter, as shown in FIG. 3B, Ni is deposited to a thickness of 15 nm by sputtering and then subjected to first heat treatment in a nitrogen atmosphere, to form silicide films 21 on the Si-exposed source/drain regions 20 and gate electrode 17. Selective etching is then performed using wet etching to remove unreacted Ni. As an example of conditions for the wet etching, a liquid mixture of sulfuric acid and hydrogen peroxide, for example, may be used. Thereafter, the silicide films 21 are subjected to second heat treatment to reduce the resistance of the silicide films 21.

As shown in FIG. 3C, W 29 is then deposited to a thickness of 30 nm by sputtering. A resist pattern (not shown) is then formed on the W 29 by lithography, and using the resist pattern as a mask, wet etching is performed to leave the W 29 only on the silicide films 21. As an example of condition for the wet etching, an alkali cleaning solution containing NH₃, H₂O₂ and H₂O may be used with a ratio of NH₃:H₂O₂:H₂O of 1:1:5.

As shown in FIG. 3D, a liner insulating film 28 made of SiN and then an interlayer insulating film 22 made of SiO₂ are deposited to respective thicknesses of 40 nm and 900 nm by CVD and flattened by CMP. A resist pattern (not shown) is formed on the interlayer insulating film 22 by lithography, and using the resist pattern as a mask, the interlayer insulating film 22 is subjected to contact etching. During this etching, the liner insulating film 28 serves as an etching stopper. Ashing is then performed, followed by cleaning. The liner insulating film 28 is then subjected to liner etching, to form contact holes 24. Ashing is then performed, followed by cleaning.

As an example of conditions for the above contact etching, a dual-frequency RIE etching apparatus may be used, C₄F₈, Ar and O₂ may be supplied at respective flow rates of 30 ml/min, 1500 ml/min and 20 ml/min, the RF power may be set at 1200 W for the upper electrode and 2000 W for the lower electrode, the pressure in the etching atmosphere may be set at 15 Pa, and the substrate temperature may be set at 20° C.

As an example of conditions for the above liner etching, a dual-frequency RIE etching apparatus may be used, CHF₃, Ar and O₂ may be supplied as etching gases at respective flow rates of 15 ml/min, 1300 ml/min and 20 ml/min, the RF power may be set at 1800 W for the upper electrode and 100 W for the lower electrode, the pressure in the etching atmosphere may be set at 15 Pa, and the substrate temperature may be set at 20° C.

As an example of the above ashing, O₂ may be supplied as an ashing gas at a flow rate of 100 ml/min, the power may be set at 2000 W for the upper electrode, the pressure in the ashing atmosphere may be set at 50 Pa and the substrate temperature may be set at 20° C. As an example of the above cleaning, an alkali cleaning solution containing NH₃, H₂O₂ and H₂O may be used with a ratio of NH₃:H₂O₂:H₂O=1:1:10.

As shown in FIG. 3E, Ti and TiN are deposited inside the contact holes by sputtering, and then W is deposited by MOCVD. W existing outside the contact holes is removed by CMP. Thus, contact plugs 25 are formed.

In this embodiment, in which W is formed only on the silicide films as in Embodiment 1, substantially the same effect as that obtained in Embodiment 1 can be obtained.

In this embodiment, which is an alteration to Embodiment 1, patterning is adopted to form the metal film only on each silicide film. This advantageously widens the choice of options of types of metal to be formed on the silicide film, compared to the case of Embodiment 1 in which selective CVD is adopted. In other words, metal other than W can be used.

### Embodiment 3

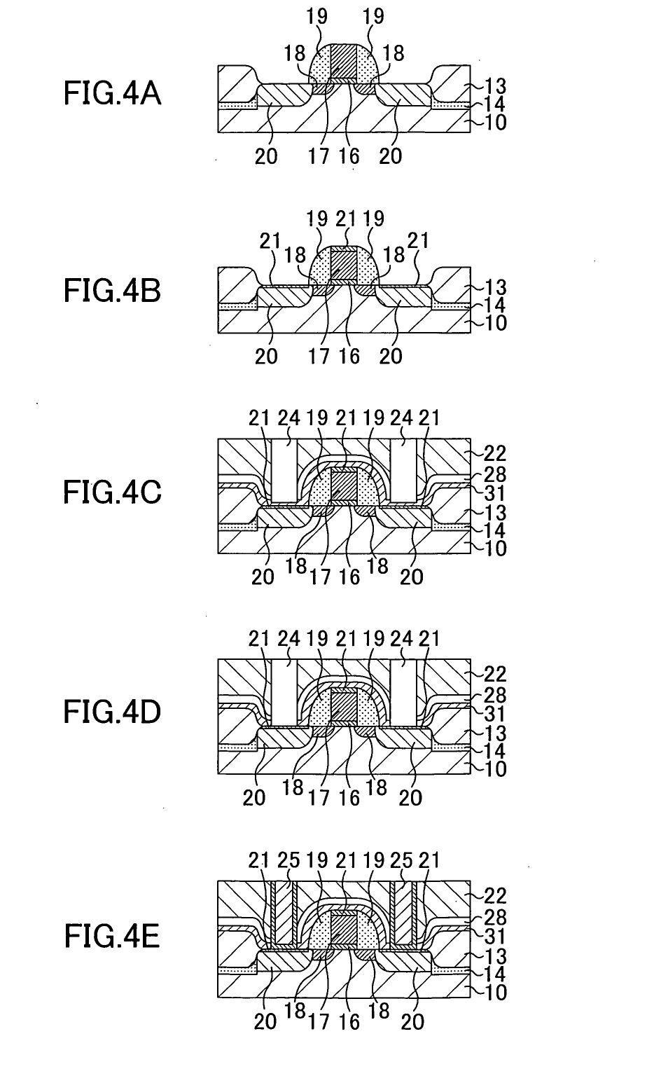

A fabrication method for a connection structure in Embodiment 3 of the present invention will be described with reference to FIGS. 4A through 4E. FIGS. 4A through 4E are cross-sectional views showing process steps of the fabrication method in this embodiment.

In the fabrication method in this embodiment, the method in Embodiment 1 is followed until the formation of the source/drain regions 20 as shown in FIG. 4A.

Thereafter, as shown in FIG. 4B, Ni is deposited to a thickness of 15 nm by sputtering, and then subjected to first heat treatment in a nitrogen atmosphere to form silicide films 21 on the Si-exposed source/drain regions 20 and gate electrode 17. Selective etching is then performed using wet etching to remove unreacted Ni. As an example of condition for the wet etching, a liquid mixture of sulfuric acid and hydrogen peroxide, for example, may be used. Thereafter, the silicide films 21 are subjected to second heat treatment to reduce the resistance of the silicide films 21.

As shown in FIG. 4C, a silicon oxide film 31 is deposited over the entire surface of the silicon substrate 10 to a thickness of 10 nm by CVD. Subsequently, a liner insulating film 28 made of SiN and then an interlayer insulating film 22 made of SiO₂ are deposited to respective thicknesses of 40 nm and 900 nm by CVD and flattened by CMP. A resist pattern (not shown) is formed on the interlayer insulating film 22 by lithography, and using the resist pattern as a mask, the interlayer insulating film 22 is subjected to contact etching. During this etching, the liner insulating film 28 serves as an etching stopper. Ashing is then performed, followed by cleaning. The liner insulating film 28 is then subjected to liner etching.

As an example of conditions for the above contact etching, a dual-frequency RIE etching apparatus may be used, C₄F₈, Ar and O₂ may be supplied at respective flow rates of 30 ml/min, 1500 ml/min and 20 ml/min, the RF power may be set at 1200 W for the upper electrode and 2000 W for the lower electrode, the pressure in the etching atmosphere may be set at 15 Pa, and the substrate temperature may be set at 20° C.

As an example of conditions for the above liner etching, a dual-frequency RIE etching apparatus may be used, CHF₃, Ar and O₂ may be supplied as etching gases at respective flow rates of 15 ml/min, 1300 ml/min and 20 ml/min, the RF power may be set at 1800 W for the upper electrode and 100 W for the lower electrode, the pressure in the etching atmosphere may be set at 15 Pa, and the substrate temperature may be set at 20° C. With the liner etching under the above conditions, the etching stops at the silicon oxide film 31 underlying the liner insulating film 28 because the selection ratio of the silicon nitride film to the silicon oxide film is as high as about 7:1. If 30% over-etching is made for the liner etching of 50 nm, the underlying silicon oxide film 31 will be etched by about 3 mm leaving the remainder of about 7 nm. The liner etching should preferably be performed under the condition that the etching ratio of the silicon nitride film to the silicon oxide film is 3 or more. With this, the liner etching can be stopped at the silicon oxide film without fail.

As shown in FIG. 4D, the remainder of the silicon oxide film 31 is removed by Ar sputter etching. As the gas species for the sputter etching, an inert gas other than Ar may also be used.

As shown in FIG. 4E, Ti and TiN are deposited inside the contact holes by sputtering and then W is deposited by MOCVD. W existing outside the contact holes is removed by CMP. Thus, contact plugs 25 are formed.

In this embodiment, the liner etching in the contact hole formation process is performed under the condition that the etching selection ratio of the silicon nitride film to the silicon oxide film is high, and thus the liner etching stops at the silicon oxide film. The remainder of the silicon oxide film, which is thin, can be easily removed by Ar sputter etching. Thus, the contact hole can be easily formed.

Also, since no oxygen or fluorocarbon gas is used during the Ar sputter etching, no ashing is required and thus the silicide films are kept from being oxidized. Therefore, with no degenerated layer being formed on the bottom of each contact hole, a highly-reliable contact plug can be formed.

### Embodiment 4

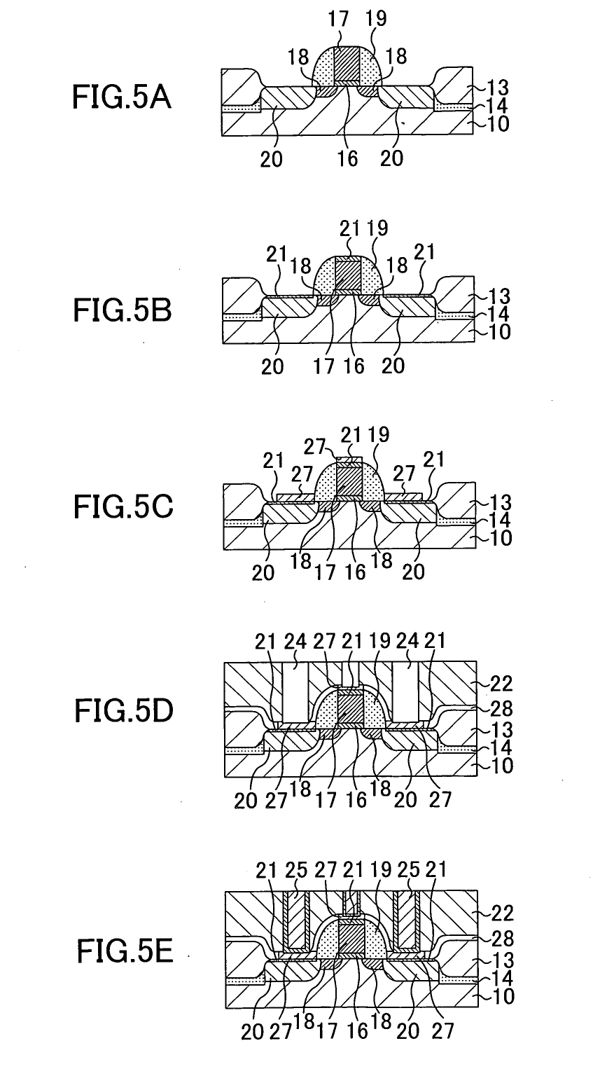

A fabrication method for a connection structure in Embodiment 4 of the present invention will be described with reference to FIGS. 5A through 5E. FIGS. 5A through 5E are cross-sectional views showing process steps of the fabrication method in this embodiment.

In the fabrication method in this embodiment, the method in Embodiment 1 is followed until the formation of the source/drain regions 20 as shown in FIG. 5A.

Thereafter, as shown in FIG. 5B, Ni is deposited to a thickness of 15 nm by sputtering and then subjected to first heat treatment in a nitrogen atmosphere, to form first silicide films 21 on the Si-exposed source/drain regions 20 and gate electrode 17. Selective etching is then performed using wet etching to remove unreacted Ni. As an example of condition for the wet etching, a liquid mixture of sulfuric acid and hydrogen peroxide, for example, may be used.

As shown in FIG. 5C, Ni is again deposited to a thickness of 15 nm by sputtering, and then subjected to second heat treatment in a nitrogen atmosphere to form second silicide films 27 on the source/drain regions 20 and gate electrode 17 each on which the first silicide film 21 has already been formed. Selective etching is then performed using wet etching to remove unreacted Ni. As an example of conditions for the wet etching, a liquid mixture of sulfuric acid and hydrogen peroxide, for example, may be used. Thereafter, the first and second silicide films 21 and 27 are subjected to third heat treatment to reduce the resistance of these silicide films. In this way, a thick silicide film made of Ni can be formed on each of the source/drain regions 20. As an example of conditions for the third heat treatment, rapid heat treatment may be performed in an Ar atmosphere at 600° C. or less.

As shown in FIG. 5D, a liner insulating film 28 made of SiN and then an interlayer insulating film 22 made of SiO₂ are deposited to respective thicknesses of 40 nm and 900 nm by CVD and flattened by CMP. A resist pattern (not shown) is formed on the interlayer insulating film 22 by lithography, and using the resist pattern as a mask, the interlayer insulating film 22 is subjected to contact etching. During this etching, the liner insulating film 28 serves as an etching stopper. Ashing is then performed, followed by cleaning. The liner insulating film 28 is then subjected to liner etching, to form contact holes 24. Ashing is then performed, followed by cleaning.

As an example of conditions for the above contact etching, a dual-frequency RIE etching apparatus may be used, C₄F₈, Ar and O₂ may be supplied at respective flow rates of 30 ml/min, 1500 ml/min and 20 ml/min, the RF power may be set at 1200 W for the upper electrode and 2000 W for the lower electrode, the pressure in the etching atmosphere may be set at 15 Pa, and the substrate temperature may be set at 20° C.

As an example of conditions for the above liner etching, a dual-frequency RIE etching apparatus may be used, CHF₃, Ar and O₂ may be supplied as etching gases at respective flow rates of 15 ml/min, 1300 ml/min and 20 ml/min, the RF power may be set at 1800 W for the upper electrode and 100 W for the lower electrode, the pressure in the etching atmosphere may be set at 15 Pa, and the substrate temperature may be set at 20° C.

As an example of the above ashing, O₂ may be supplied as an ashing gas at a flow rate of 100 ml/min, the power may be set at 2000 W for the upper electrode, the pressure in the ashing atmosphere may be set at 50 Pa and the substrate temperature may be set at 20° C. As an example of the above cleaning, a hydrofluoric-nitric acid may be used at a ratio of HF:HNO₃:H₂O=1:1:300.

Any degenerated layer formed on the bottom of each contact hole is then removed by Ar sputter etching.

As shown in FIG. 5E, Ti and TiN are deposited inside the contact holes by sputtering and then W is deposited by MOCVD. W existing outside the contact holes 24 is removed by CMP. Thus, contact plugs 25 are formed.

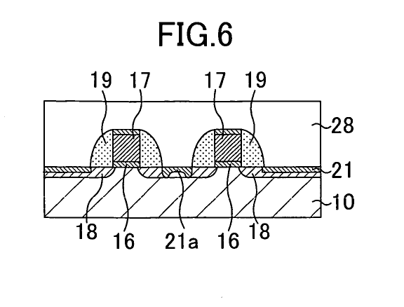

In this embodiment, Ni as the same metal as the first silicide film made of Ni is deposited on the first silicide layer to form a second silicide film. The reason for forming the silicide film in two steps as described above is as follows. If the first silicide film is deposited thickly to obtain a thick silicide film at one time, unreacted Ni may react with the silicon substrate 10 in a portion between adjacent gate electrodes 17, forming a locally thick silicide film 21a as shown in FIG. 6. By depositing Ni in two steps as in this embodiment, no unreacted Ni in the first silicidation will be left behind, and thus a uniform thick silicide film can be formed.

Also, although the silicide film exposed on the bottom of each contact hole is subjected to oxidation with oxygen supplied during the contact etching and the ashing, it is only the upper portion of the thick silicide film that is actually oxidized. Therefore, after the subsequent removal of a degenerated layer by Ar sputter etching, the silicide film underlying the degenerated layer is kept unremoved. Thus, a low-resistance contact plug can be formed.

Although a NMIS transistor portion was exemplified to describe the present invention in this embodiment, such a contact plug can also be formed for a PMIS transistor portion by substantially the same technique, and substantially the same effect can be obtained.

### Embodiment 5

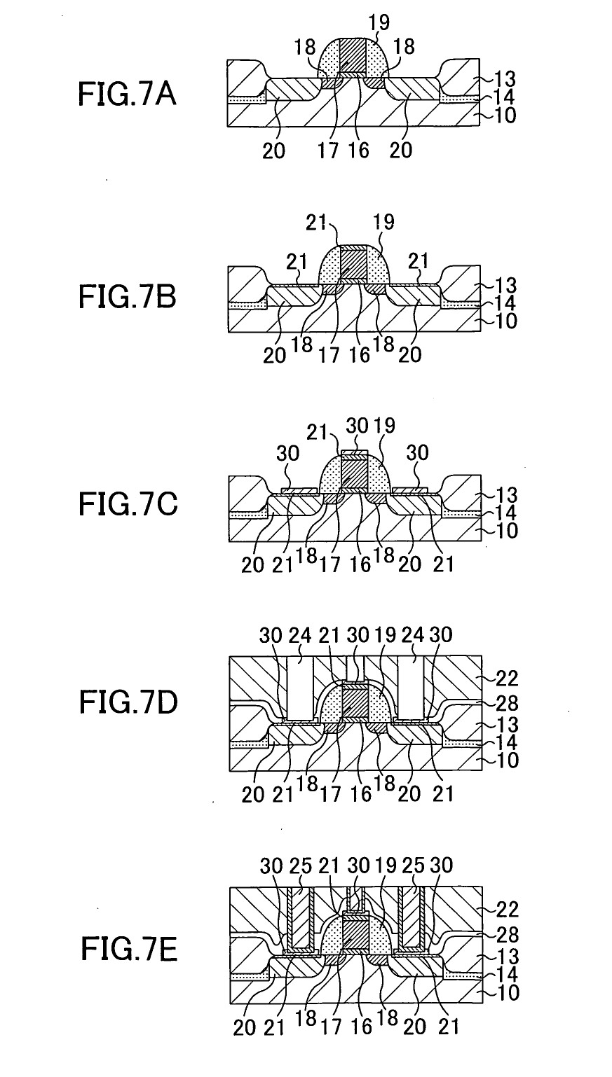

A fabrication method for a connection structure in Embodiment 5 of the present invention will be described with reference to FIGS. 7A through 7E. FIGS. 7A through 7E are cross-sectional views showing process steps of the fabrication method in this embodiment.

In the fabrication method in this embodiment, the method in Embodiment 1 is followed until the formation of the source/drain regions 20 as shown in FIG. 7A.

Thereafter, as shown in FIG. 7B, Ni is deposited to a thickness of 15 nm by sputtering and then subjected to first heat treatment in a nitrogen atmosphere, to form first silicide films 21 on the Si-exposed source/drain regions 20 and gate electrode 17. Selective etching is then performed using wet etching to remove unreacted Ni. As an example of conditions for the wet etching, a liquid mixture of sulfuric acid and hydrogen peroxide, for example, may be used.

As shown in FIG. 7C, Ti is deposited to a thickness of 20 μm by sputtering and then subjected to second heat treatment in a nitrogen atmosphere, to form second silicide films 30 on the source/drain regions 20 and the gate electrode 17 each on which the first silicide film 21 has already been formed. Selective etching is then performed using wet etching to remove unreacted Ti. As an example of conditions for the wet etching, a liquid mixture of sulfuric acid and hydrogen peroxide, for example, may be used. Thereafter, the first and second silicide films 21 and 30 are subjected to third heat treatment to reduce the resistance of these films. As an example of conditions for the third heat treatment, a rapid heat treatment method may be performed in an Ar atmosphere at 600° C. or less.

As shown in FIG. 7D, a liner insulating film 28 made of SiN and then an interlayer insulating film 22 made of SiO₂ are deposited to respective thicknesses of 40 nm and 900 nm by CVD and flattened by CMP. A resist pattern (not shown) is formed on the interlayer insulating film 22 by lithography, and using the resist pattern as a mask, the interlayer insulating film 22 is subjected to contact etching. During this etching, the liner insulating film 28 serves as an etching stopper. Ashing is then performed, followed by cleaning. The liner insulating film 28 is then subjected to liner etching, to form contact holes 24. Ashing is then performed, followed by cleaning.

As an example of conditions for the above contact etching, a dual-frequency RIE etching apparatus may be used, C₄F₈, Ar and O₂ may be supplied at respective flow rates of 30 ml/min, 1500 ml/min and 20 ml/min, the RF power may be set at 1200 W for the upper electrode and 2000 W for the lower electrode, the pressure in the etching atmosphere may be set at 15 Pa, and the substrate temperature may be set at 20° C.

As an example of conditions for the above liner etching, a dual-frequency RIE etching apparatus may be used, CHF₃, Ar and O₂ may be supplied as etching gases at respective flow rates of 15 ml/min, 1300 ml/min and 20 ml/min, the RF power may be set at 1800 W for the upper electrode and 100 W for the lower electrode, the pressure in the etching atmosphere may be set at 15 Pa, and the substrate temperature may be set at 20° C.

As an example of the above ashing, O₂ may be supplied as an ashing gas at a flow rate of 100 ml/min, the power may be set at 2000 W for the upper electrode, the pressure in the ashing atmosphere may be set at 50 Pa, and the substrate temperature may be set at 20° C. As an example of the above cleaning, a hydrofluoric-nitric acid may be used at a ratio of HF:HNO₃:H₂O=1:1:300.

Any degenerated layer formed on the bottom of each contact hole is then removed by Ar sputter etching.

As shown in FIG. 7E, Ti and TiN are deposited inside the contact holes by sputtering and then W is deposited by MOCVD. W existing outside the contact holes is removed by CMP, to thereby form contact plugs 25.

In this embodiment, the second silicide layer made of Ti is formed on the first silicide layer made of Ni. Therefore, with supply of oxygen during the contact etching and the ashing, the titanium silicide film exposed on the bottom of each contact hole is oxidized.

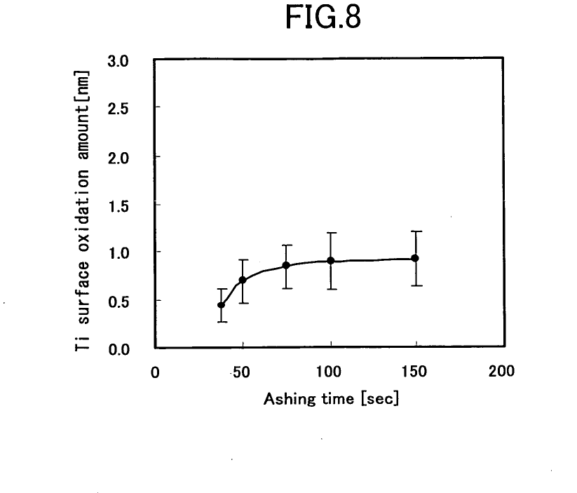

FIG. 8 shows the relationship between the Ti oxidation time and the Ti surface oxidized film thickness. It is found from FIG. 8 that with increase of the oxidation time, a dense oxidized layer is formed in the surface portion of the titanium, and this lowers the oxidation rate. In other words, titanium oxide is formed on the surface of the titanium silicide film during the contact etching and the ashing, and this formation of the titanium oxide blocks further progress of the oxidation. Therefore, the underlying first silicide film is prevented from being oxidized, and thus does not cause formation of a degeneration layer. A high-resistance degenerated layer formed on the titanium silicide film is then removed by Ar sputter etching, and thus a low-resistance contact plug can be formed.

Although a NMIS transistor portion was exemplified to describe the present invention in this embodiment, such a contact plug can also be formed for a PMIS transistor portion by substantially the same technique, and substantially the same effect can be obtained.

As described above, the connection structure and the fabrication method for the same according to the present invention are high in industrial applicability in the aspect that formation of a high-resistance degenerated layer can be prevented during the contact etching and the liner etching in the connection portion formation process.

While the present invention has been described in preferred embodiments, it will be apparent to those skilled in the art that the disclosed invention may be modified in numerous ways and may assume many embodiments other than that specifically set out and described above. Accordingly, it is intended by the appended claims to cover all modifications of the invention which fall within the true spirit and scope of the invention.

What is claimed is:

1. A connection structure comprising:
a conductive layer formed in or on a substrate;
a silicide film formed in a predetermined region on the conductive layer;
a metal film formed on the silicide film;
an insulating film formed over the substrate including the metal film; and
a contact plug formed in the insulating film, the bottom of the contact plug being in contact with the metal film.

2. A connection structure comprising:
a conductive layer formed in or on a substrate;
a first silicide film formed in a predetermined region on the conductive layer;
a second silicide film formed on the first silicide film;
an insulating film formed over the substrate including the second silicide film; and
a contact plug formed in the insulating film, the bottom of the contact plug being in contact with the second silicide film.

3. The connection structure of claim 2, wherein the first silicide film and the second silicide film are silicide films including a same element.

4. The connection structure of claim 2, wherein the first silicide film and the second silicide film are silicide films including different elements from each other.

5. A fabrication method for a connection structure, comprising the steps of:
(a) forming a conductive layer in or on a substrate;
(b) forming a first metal film on the conductive layer;
(c) forming a silicide film selectively on the conductive layer by performing heat treatment to allow the first metal film to react with the conductive layer;
(d) forming a second metal film only on the silicide film;
(e) forming an insulating film over the substrate including the second metal film;
(f) forming a contact hole reaching the second metal film by removing a predetermined region of the insulating film; and
(g) removing a degenerated layer formed on the surface of the second metal film existing on the bottom of the contact hole by cleaning the inside of the contact hole.

6. The fabrication method of claim 5, wherein in the step (d), the second metal film is formed only on the silicide film by selective CVD.

7. The fabrication method of claim 5, wherein in the step (d), the second metal film is formed over the substrate including the silicide film, and then the second metal film is selectively removed using a mask to be left behind only on the silicide film.

8. The fabrication method of claim 5, wherein the heat treatment is performed by rapid thermal annealing (RTA).

9. A fabrication method for a connection structure, comprising the steps of:
(a) forming a conductive layer in or on a substrate;
(b) forming a first metal film on the conductive layer;
(c) forming a silicide film selectively on the conductive layer by performing heat treatment to allow the first metal film to react with the conductive layer;
(d) forming a first insulating film over the substrate including the silicide film;
(e) forming a second insulating film on the first insulating film;
(f) forming a contact hole reaching the first insulating film by removing a predetermined region of the second insulating film; and
(g) removing the first insulating film exposed in the contact hole by sputter etching to allow the silicide film to be exposed in the contact hole.

10. The fabrication method of claim 9, wherein in the step (f), the etching rate ratio of the second insulating film to the first insulating film is 3 or more.

11. The fabrication method of claim 9, wherein the heat treatment is performed by rapid thermal annealing (RTA).

12. A fabrication method for a connection structure, comprising the steps of:
forming a conductive layer in or on a substrate;
forming a first metal film on the conductive layer;
forming a first silicide film selectively on the conductive layer by performing heat treatment to allow the first metal film to react with the conductive layer;
forming a second metal film on the conductive layer;
forming a second silicide film selectively on the first silicide film by performing heat treatment to allow the second metal film to react with the first silicide film;
forming an insulating film over the substrate including the second silicide film;
forming a contact hole reaching the second silicide film by removing a predetermined region of the insulating film; and
removing a degenerated layer formed on the surface of the second silicide film existing on the bottom of the contact hole by sputter etching.

13. The fabrication method of claim 12, wherein the first silicide film and the second silicide film are silicide films including a same element.

14. The fabrication method of claim 12, wherein the first silicide film and the second silicide film are silicide films including different elements from each other.

15. The fabrication method of claim 12, wherein the heat treatment is performed by rapid thermal annealing (RTA).
